(19) United States
(12) Patent Application Publication
(10) Pub. No.: US 2025/0185277 A1
(43) Pub. Date: Jun. 5, 2025

(54) MULTI-GATE SWITCH FIELD EFFECT TRANSISTOR

(71) Applicant: Wolfspeed, Inc., Durham, NC (US)

(72) Inventors: Kyle Bothe, Cary, NC (US); Tom Smith, Raleigh, NC (US)

(21) Appl. No.: 18/526,986

(22) Filed: Dec. 1, 2023

(51) Int. Cl. H01L 29/778; H01L 29/20; H01L 29/66

(52) U.S. Cl. CPC H10D 30/4755; H10D 30/015; H10D 62/8503

(57) ABSTRACT

A multi-gate switch field effect transistor, FET, according to some embodiments includes a semiconductor structure, a source contact on the semiconductor structure, and a drain contact on the semiconductor structure. The multi-gate switch FET further includes a first gate on the semiconductor structure between the source contact and the drain contact; and a second gate on the semiconductor structure adjacent to the first gate and between the source contact and the drain contact. The multi-gate switch FET further includes a conducting region in the semiconductor structure between the first gate and the second gate.

### FIELD

The disclosure relates to semiconductor devices and, more particularly, to multi-gate field effect transistors (FETs).

### BACKGROUND

Electronic devices formed in lower bandgap semiconductor materials such as silicon and gallium arsenide have found wide application in lower power and (in the case of silicon) lower frequency applications. These semiconductor materials may be less well suited for higher power and/or high frequency applications, however, because of their relatively small bandgaps (e.g., 1.12 eV for silicon and 1.42 eV for gallium arsenide at room temperature) and/or relatively small breakdown voltages.

For high power, high temperature, and/or high frequency applications, devices formed in wide bandgap semiconductor materials such as silicon carbide (2.996 eV bandgap for alpha silicon carbide at room temperature) and the Group III nitrides (e.g., 3.36 eV bandgap for gallium nitride at room temperature) are often used. These materials, typically, have higher electric field breakdown strengths and higher electron saturation velocities as compared to gallium arsenide and silicon.

A device of particular interest for high power and/or high frequency applications is the High Electron Mobility Transistor (HEMT). HEMT devices may offer operational advantages in a number of applications. In operation, a two-dimensional electron gas (2DEG) is formed in a HEMT device at the heterojunction of two semiconductor materials with different bandgap energies, where the smaller bandgap material has a higher electron affinity. The 2DEG is an accumulation layer in the smaller bandgap material and can contain a very high sheet electron concentration. Additionally, electrons that originate in the wider-bandgap semiconductor material transfer to the 2DEG layer, allowing a high electron mobility due to reduced ionized impurity scattering. This combination of high carrier concentration and high carrier mobility can give the HEMT a very large transconductance and may provide a strong performance advantage over metal oxide semiconductor field effect transistors (MOSFETs) for high-frequency applications.

High electron mobility transistors fabricated in Group Ill-nitride based material systems have the potential to generate large amounts of radio frequency (RF) power because of the combination of material characteristics that includes the aforementioned high breakdown fields, wide bandgaps, large conduction band offset, and/or high saturated electron drift velocity.

Modern communication devices, for example, are often required to support various communication standards that employ different modulation techniques over a wide range of operating RFs. These standards include but are not limited to the Global System for Mobile Communications (GSM), Personal Communication Service (PCS), Universal Mobile Telecommunications Systems (UMTS), Worldwide Interoperability for Microwave Access (WiMAX), Long Term Evolution (LTE), fifth generation (5G), sixth generation (6G), and the like.

The bands of operation for these standards range from around 800 MHz to at least 20 GHz. The GSM standards employ bands ranging from around 800 MHz to 2 GHz. For example, GSM-850 uses an 824-894 MHz band, GSM-900 uses an 890-960 MHz band, GSM-1800 uses a 1310-1880 MHz band, and GSM-1900 uses an 1850-1990 MHz band. UMTS uses a 2.11-2.17 GHz band. LTE uses a 2.6-2.7 GHz band; WiMAX uses bands centered about 2.3, 2.5, 3.3 and 3.5 GHz; 5G uses a 1-6 GHz range; and 6G may use frequencies in at least the range 7-20 GHz.

Electrical circuits requiring high power handling capability while operating at high frequencies, such as radio frequencies (500 MHZ), S-band (3 GHZ) and X-band (10 GHz), and greater (e.g. 20 GHz) have in recent years become more prevalent. Because of the increase in high power, high frequency circuits, there has been a corresponding increase in demand for transistors which are capable of reliably operating RFs while still being capable of handling higher power loads.

Moreover, FETs (e.g., GaN HEMTs) may be utilized for high power radio frequency (RF) applications, such as high power switching applications, and there is an ever increasing demand for improved RF performance. Conventional FETs, however, may not be enough to meet RF performance needs.

### SUMMARY

A multi-gate switch FET according to some embodiments includes a semiconductor structure, a source contact on the semiconductor structure, and a drain contact on the semiconductor structure. The multi-gate switch FET further includes a first gate on the semiconductor structure between the source contact and the drain contact; and a second gate on the semiconductor structure adjacent to the first gate and between the source contact and the drain contact. The multi-gate switch FET further includes a conducting region in the semiconductor structure between the first gate and the second gate.

The conducting region may include an N-plus material.

The conducting region may include a Group III nitride doped with at least one of silicon (Si) and germanium (Ge).

The conducting region may include a Group Ill nitride implanted with at least one of Si and Ge.

The conducting region may include a regrowth N-plus layer of gallium nitride (GaN).

The conducting region may include an N-plus material and an ohmic metal on the N-plus material.

The conducting region may be positioned between a first portion of the semiconductor structure and a second portion of the semiconductor structure.

In some embodiments, the multi-gate switch FET further includes a first portion of a dielectric material on the semiconductor structure. The first portion of the dielectric material has a first length that extends from a first edge of the source contact to a first edge of the first gate. The multi-gate switch FET further includes a second portion of the dielectric material on the conducting region and on the first and second portions of the semiconductor substrate. The second portion of the dielectric material includes (i) a second length that extends from a second edge of the first gate to a first edge of the conducting region, (ii) a third length that extends from the first edge of the conducting region to a second edge of the conducting region, and (iii) a fourth length that extends from the second edge of the conducting region to a second edge of the second gate. The multi-gate switch FET further includes a third portion of the dielectric material on the semiconductor substrate. The third portion of the dielectric material has a fifth length that extends from a first edge of the drain contact to a first edge of the second gate.

The first length and the fifth length may be about the same.

A distance between a second edge of the first gate and a second edge of the second gate may be about equal to about the second length plus the fourth length plus the third length.

The first length and the second length may be about the same.

The fourth length and the fifth length may be about the same.

The first length, the second length, the fourth length, and the fifth length may be about the same.

The third length may be in a range from about 1 μm to about 4 μm.

The conducting region may have a sheet resistance in a range from about 30 ohms per square to about 200 ohms per square.

A multi-gate switch FET according to some other embodiments includes a semiconductor structure, a source contact on the semiconductor structure, and a drain contact on the semiconductor structure. The multi-gate switch FET further includes a first gate on the semiconductor structure between the source contact and the drain contact; and a second gate on the semiconductor structure adjacent to the first gate and between the source contact and the drain contact. The multi-gate switch FET further includes a first conducting region in the semiconductor structure including a first portion positioned between the first gate and the second gate and a second portion and is connected to at least one of a ground, the source contact, and the drain contact.

In some embodiments, the second portion of the first conducting region is connected to the ground.

The first gate may include a first gate finger, the second gate may include a second gate finger, and the second portion of the first conducting region may be positioned under at least one of the first gate finger and the second gate finger.

In some embodiments, the multi-gate switch FET further includes a third gate on the semiconductor structure adjacent to the second gate and between the source contact and the drain contact; and a second conducting region in the semiconductor structure including at least a third portion positioned between the second gate and the third gate.

The first conducting region may include an N-plus material.

The first conducting region may include a Group Ill nitride doped with at least one of Si and Ge.

The first conducting region may include a Group III nitride implanted with at least one of Si and Ge.

The first conducting region may include a regrowth N-plus layer of GaN.

The first conducting region may include an N-plus material and an ohmic metal on the N-plus material.

The first conducting region may be positioned between a first portion of the semiconductor structure and a second portion of the semiconductor structure.

In some embodiments, the multi-gate switch FET further includes a first portion of a dielectric material on the semiconductor structure. The first portion of the dielectric material has a first length that extends from a first edge of the source contact to a first edge of the first gate. The multi-gate switch FET further includes a second portion of the dielectric material on the conducting region and on the first and second portions of the semiconductor substrate. The second portion of the dielectric material includes (i) a second length that extends from a second edge of the first gate to a first edge of the conducting region, (ii) a third length that extends from the first edge of the conducting region to a second edge of the conducting region, and (iii) a fourth length that extends from the second edge of the conducting region to a second edge of the second gate. The multi-gate switch FET further includes a third portion of the dielectric material on the semiconductor substrate. The third portion of the dielectric material has a fifth length that extends from a first edge of the drain contact to a first edge of the second gate.

The first length and the fifth length may be about the same.

A distance between a second edge of the first gate and a second edge of the second gate may be about equal to about the second length plus the fourth length plus the third length.

The first length and the second length may be about the same.

The fourth length and the fifth length may be about the same.

The first length, the second length, the fourth length, and the fifth length may be about the same.

The third length may be in a range from about 1 μm to about 4 μm.

The conducting region may have a sheet resistance in a range from about 30 ohms per square to about 200 ohms per square.

Additional features, advantages, and aspects of the disclosure may be set forth or apparent from consideration of the following detailed description, drawings, and claims. Moreover, it is to be understood that both the foregoing summary of the disclosure and the following detailed description includes examples and intended to provide further explanation without limiting the scope of the disclosure as claimed.

### BRIEF DESCRIPTION OF THE DRAWINGS

The accompanying drawings, which are included to provide a further understanding of the disclosure, are incorporated in, and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is a schematic diagram showing a cross section view of a switch FET.

FIG. 2 is a schematic diagram showing a plan view of a multi-finger switch FET.

FIG. 3 is a schematic diagram of series combined stacked switch FETs showing a resistor connected to the internal source/drain node to DC bias to ground potential.

FIG. 4A is a schematic diagram showing a cross section view of combined stacked FET is to combine series connected channels at the cell level.

FIG. 4B is a schematic diagram showing a cross section view of an example device that eliminates the pad entirely with internally stacked dual-gate switch FETs.

FIG. 5 is a schematic diagram showing a cross section view of a multi-gate switch FET according to some embodiments.

FIG. 6A is a schematic diagram showing a cross section view of a multi-gate switch FET according to some embodiments.

FIG. 6B is a schematic diagram showing a cross section view of a multi-gate switch FET according to some other embodiments.

FIG. 6C is a schematic diagram showing a plan view of a multi-gate switch FET according to some embodiments.

FIG. 7 is a schematic diagram showing a cross section view of a multi-gate switch FET according to some other embodiments.

FIG. 8 is a schematic diagram showing a plan view of a multi-gate switch FET according to some other embodiments.

### DETAILED DESCRIPTION OF THE DISCLOSURE

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element is referred to as being “connected” or “coupled” to another element, it can be directly connected or coupled to the another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

It may be desirable to design FETs for RF switch circuits to minimize on-resistance and off-state capacitance while being able to withstand large voltages swings while the gate is in reverse bias.

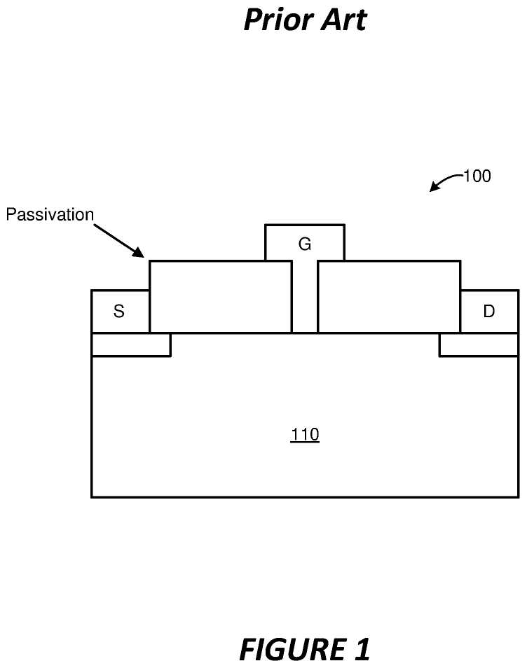

FIG. 1 is a cross section view of a conventional switch FET 100 channel showing the source S, drain D, and gate G of the device 100, where the gate G is in the center of the source S and drain D contacts.

When high power operation is needed and a FET is biased into pinchoff, the switch FET needs to be able to withstand RF peak voltage over the gate-drain junction and gate-source junction while remaining below pinchoff. This requires increased breakdown voltage in the switch FET. Two approaches that may be used to make the switch circuit handle more voltage include: (1) increase the channel length of the switch FET, or (2) place multiple switch FETs in a series configuration along the drain-source path. While the first approach may achieve increased breakdown voltage, the second approach may increase the effective breakdown voltage without requiring a higher control voltage to switch. Thus, the gate bias to each FET can remain at a less negative voltage and using a high voltage driver circuit may be avoided to control the gate voltage to the switch. This may be desirable because high voltage driver circuits are more difficult to obtain and generally switch slower than low voltage drivers.

Placing switch FETs in series combination so that the source of one FET is connected to the drain of a second (or third, etc.) FET may also be referred to as stacking FETs.

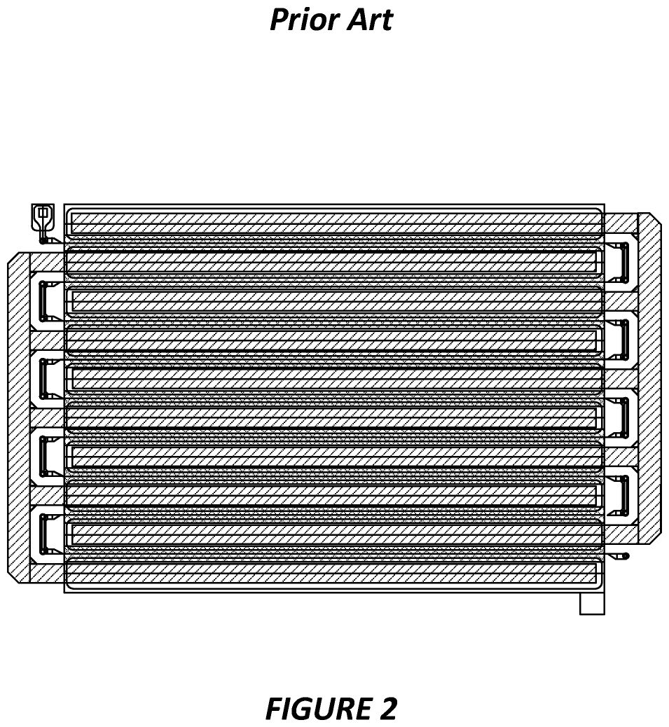

It is noted that a single switch FET can include many individual channels arranged in a parallel combination so that the FET performance is maintained at high frequency while having the characteristics of a large device. An example of a switch FET with nine channels combined in parallel is shown in FIG. 2. The channels may be referred to as “fingers”, in which case the example in FIG. 2 may be referred to as a nine-finger switch FET.

The respective channels in FIG. 2 may each have a dimension D of 250 μm, for example, for a total size of 2.25 mm, for example.

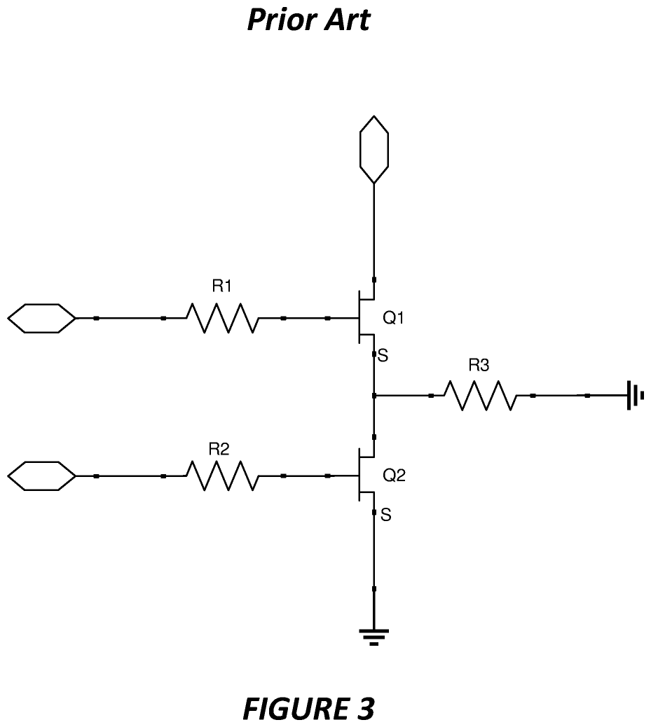

However, when switch FETs are stacked, the internal drain/source node common to both FETs needs to be DC biased to ground potential so that each gate-source and gate-drain junction of the FETs is biased to minimize the junction capacitances of each device, which in turn minimizes the total off-capacitance of the stacked switch FETs. This may be accomplished by including a large value resistor R3 connected between the internal common source/drain node and ground as shown in the example in FIG. 3.

When stacking switch FET cells that include multiple fingers as in FIG. 2, for example, the layout area increases (e.g., significantly) since the switch FETs can take up a large portion of the circuit area. Additionally, the metallization of each FET can form a capacitance to ground, thereby increasing the total off-capacitance of FETs used to connect to ground. The majority of this added capacitance may be due to the additional drain and source pads at the common internal source and drain node.

One approach to reducing the footprint, as well as improving the on-resistance, of the combined stacked FET may be to combine the series connected channels at the cell level.

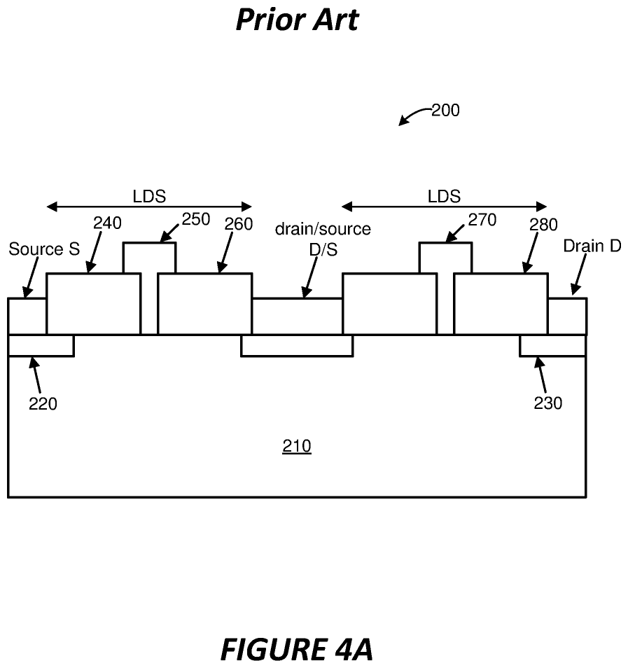

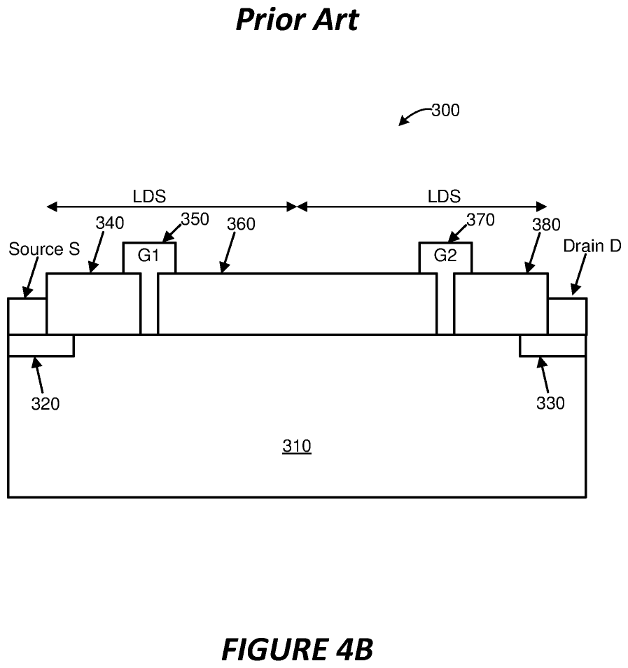

A cross section of this approach is shown in FIG. 4A. FIG. 4A is a cross section of two switch FETS stacked for a more compact layout. The stacked switch FET 200 includes a semiconductor structure 210, a source contact S, a drain contact D, and a shared drain/source (D/S) contact on the semiconductor structure 210. Further, a first gate 250 and a second gate 270 are provided on the semiconductor structure 210. Passivation material 240, 260, 280 is also provided on the semiconductor structure 210. Two lengths between the source S and the drain/source (D/S) and between the drain/source (D/S) and drain D are denoted as “LDS”, respectively, are about the same.

The approach shown in FIG. 4A, however, does not eliminate the internal drain/source (D/S) pad and an additional manifold is needed to DC bias the pad to ground reference.

A disadvantage of the internal drain/source pad of FIG. 4A, for example, may be an increase in the total on resistance due to the resistance of the metal and the ohmic-contact resistance between the semiconductor and the metal.

Reducing the size of the pad to a minimum may have an advantage of reducing the parasitic capacitance associated with the pad. FIG. 4B is a cross section diagram illustrating an example that eliminates the pad entirely with internally stacked dual-gate switch FETs.

The dual-gate switch FET 300 example of FIG. 4B stacks two devices in series for increased voltage handling. The stacked dual-gate switch FET 300 includes a semiconductor structure 310, a source contact S and a drain contact D on the semiconductor structure 310. A first gate 350 and a second gate 370 are provided on the semiconductor structure 310. Passivation material 340, 360, 380 is also provided on the semiconductor structure 310. Two lengths between the source S and about the midway point of the internal node and between about the midway point of the internal node and drain D are denoted as “LDS”, respectively, are about the same.

While the approach shown in FIG. 4B may eliminate the parasitic off-capacitance associated with the internal source/drain pad, and may reduce on-resistance by eliminating the contact resistance to the pad metallization, it does not provide a way of applying a DC bias to the internal node. Consequently, since the bias voltage to each gate is the same, the voltage between gates is zero volts and capacitance between the gates and the channel material between the two gate is maximum.

Thus, there is a need for improving the RF performance of high power RF switches using multi-gate switch FETs.

The present disclosure provides an approach that allows the DC bias to be applied to a point between the gates without incurring a significant increase in the off-capacitance, while still increasing the voltage handling of the FETs and minimizing the on-resistance.

While some embodiments herein are described with reference to certain configurations that include two of three gates and a conducting region, the disclosure is not so limited and other versions are possible. The multi-gate switch FET can include any number of gates greater than one and can have may different configurations (e.g., multiple conducting regions when there are more than two gates, serpentine patterns of the gates and conducting region(s), etc.). Accordingly, the spirit and scope of the invention should not be limited to the specific example embodiments described herein.

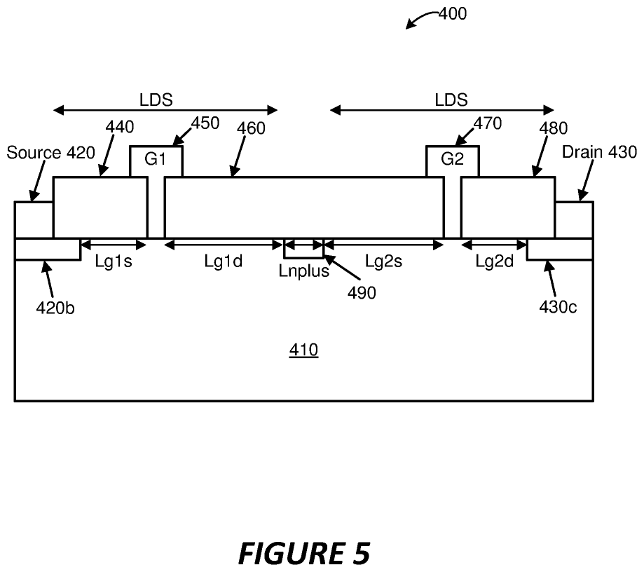

FIG. 5 is a cross section view of a dual gate switch FET in accordance with some embodiments. As shown, the example dual gate switch FET 400 includes a region 490 of N-plus material (also referred to herein as a “conducting region”) that allows DC bias of the internal node to reduce the total off-capacitance while allowing minimization of total on-resistance and improved voltage handling of the switch FET.

Thus, in the example embodiment shown in FIG. 5, the N-plus region 490 is positioned between the stacked FETs and is externally contacted to DC bias and, thus, the total off-capacitance of the stacked switch FET may be reduced.

As shown in FIG. 5, in some embodiments, a multi-gate switch FET 400 is provided. The multi-gate switch FET 400 includes a semiconductor structure 410, and a source contact 420 and a drain contact 430 on the semiconductor structure 410. Further, a first gate (G1) 450 is provided on the semiconductor structure 410 between the source contact 420 and the drain contact 430. A second gate (G2) 470 is provided on the semiconductor structure 410 adjacent to the first gate 450 and between the source contact 420 and the drain contact 430. A conducting region 490 is included in the semiconductor structure 410 between the first gate 450 and the second gate 470.

The semiconductor structure 410 may include a Group II-nitride material such as GaN, aluminum GaN (AlGaN), aluminum nitride (AlN), indium aluminum GaN (InAlGaN), and/or another suitable material.

As discussed, in some embodiments, the conducting region 490 includes N-plus material. The N-plus material of the conducting region 490 may include a Group III nitride doped with at least one of silicon (Si) and germanium (Ge).

In some embodiments, the conducting region 490 includes a Group III nitride doped with at least one of Si and Ge.

In another embodiment, the conducting region 490 includes a Group Ill nitride implanted with at least one of Si and Ge.

In yet another embodiment, the conducting region 490 includes a regrowth N-plus layer of GaN.

In a further embodiment, the conducting region 490 includes an N-plus material and an ohmic metal on the N-plus material.

In the embodiment shown in FIG. 5, there are two gates 450, 470 between source 420 and drain 430 ohmic contacts. Source contact 420 is on a region 420b of N-plus material in the semiconductor structure 410. Further, drain contact 430 is on a region 430c of N-plus material in the semiconductor structure 410.

As shown in the embodiment in FIG. 5, the conducting region 490 is positioned between a first portion of the semiconductor structure 410 and a second portion of the semiconductor structure 410. A first portion of a dielectric material 440 is on the semiconductor structure 410. The first portion of the dielectric material 440 has a first length denoted as “Lg1s” that extends from a first edge of the source contact 420 to a first edge of the first gate 450.

A second portion of the dielectric material 460 is on the conducting region 490 and on the first and second portions of the semiconductor substrate 410. The second portion of the dielectric material 490 includes (i) a second length denoted as “Lg1d” that extends from a second edge of the first gate 450 to a first edge of the conducting region 490, (ii) a third length denoted as “Lnplus” that extends from the first edge of the conducting region 490 to a second edge of the conducting region 490, and (iii) a fourth length denote as “Lg2s” that extends from the second edge of the conducting region 490 to a second edge of the second gate 470.

Further, a third portion of the dielectric material 480 is on the semiconductor substrate 410. The third portion of the dielectric material 480 has a fifth length denoted as “Lg2d” that extends from a first edge of the drain contact 430 to a first edge of the second gate 470.

The dielectric material 440, 460, 480 may be silicon nitride (SiN) or another suitable material.

In some embodiments, the first length (also referred to herein as a “distance”) Lg1s between the source contact 420 and the first gate 450 is and the fifth length Lg2d between the drain contact 430 and the second gate have the same dimension, or about the same dimension (e.g., within manufacturing tolerances).

Further, in some embodiments, a distance between the second edge of the first gate 450 and a second edge of the second gate 470 is about equal to about the second length Lg1d plus the fourth length Lg2s plus the third length Lnplus.

In some embodiments, the first length Lg1s and the second length Lg1d have the same dimension, or about the same dimension (e.g., within manufacturing tolerances).

Further, in some embodiments, the fourth length Lg2s and the fifth length Lg2d have the same dimension, or about the same dimension (e.g., within manufacturing tolerances).

In some embodiments, the first length Lg1s, the second length Lg1d, the fourth length Lg2s, and the fifth length Lg2d have the same dimension, or about the same dimension (e.g., within manufacturing tolerances).

In some embodiments, the third length Lnplus is in a range from about 1 μm to about 4 μm.

While various lengths discussed above have been described in considerable detail with reference to certain configurations thereof, other versions are possible. For example, the lengths that are described as about equal or about the same may be different lengths that provide the desired improved RF performance. Accordingly, the spirit and scope of the invention should not be limited to the specific embodiments described herein.

The conducting region 490 may have a sheet resistance in a range from about 30 ohms per square to about 200 ohms per square.

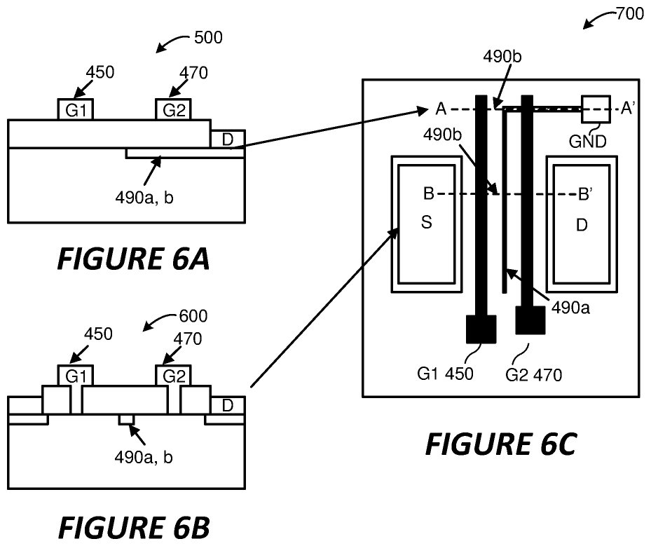

FIG. 6A is a cross section view of an example embodiment of a multi-gate switch FET 500 where the conducting region 490 in the semiconductor structure 410 includes a first portion 490a positioned between the first gate 450 and the second gate 470 and a second portion 490b that extends from the first portion 490a and is connected to ground (GND).

FIG. 6B is a cross section view of another example embodiment of a multi-gate switch FET 600 where the conducting region 490 in the semiconductor structure 410 includes a first portion 490a positioned between the first gate 450 and the second gate 470 and a second portion 490b that extends from the first portion 490a and is positioned under at least one of the source contact 420 and the drain contact 430.

FIG. 6C is a plan view showing the example embodiments of multi-gate switch FETs shown in FIGS. 6A and 6B.

Thus, in FIG. 6C, in one embodiment, the multi-gate switch FET 700 includes a semiconductor structure 410, and a source contact 420 and a drain contact 430 on the semiconductor structure 410. Further, the first gate (G1) 450 is provided on the semiconductor structure 410 between the source contact 420 and the drain contact 430. A second gate (G2) 470 is provided on the semiconductor structure 410 adjacent to the first gate 450 and between the source contact 420 and the drain contact 430. The conducting region 490 in the semiconductor structure 410 includes a first portion 490a positioned between the first gate 450 and the second gate 470 and a second portion 490b shown with dashed line A-A′ that extends from the first portion 490a and is connected to GND.

Additionally, in FIG. 6C, in another embodiment, the multi-gate switch FET 700 includes a semiconductor structure 410, and a source contact 420 and a drain contact 430 on the semiconductor structure 410. Further, the first gate (G1) 450 is provided on the semiconductor structure 410 between the source contact 420 and the drain contact 430. A second gate (G2) 470 is provided on the semiconductor structure 410 adjacent to the first gate 450 and between the source contact 420 and the drain contact 430. The conducting region 490 in the semiconductor structure 410 includes a first portion 490a positioned between the first gate 450 and the second gate 470 and a second portion 490b shown with dashed line B-B′ that extends from the first portion 490a and is positioned under at least one of the source contact 420 and the drain contact 430.

Thus, as shown in FIG. 6C, the second portion 490b of the first conducting region can extend from the first portion 490a and is connected to at least one of a ground, the source contact 420, and the drain contact 430.

As further shown in FIG. 6C, in some embodiments, the first gate 450 includes a first gate finger; and the second gate 470 includes a second gate finger. The second portion 490b of the first conducting region 490 is positioned under at least one of the first gate finger and the second gate finger as shown by the dashed line B-B′.

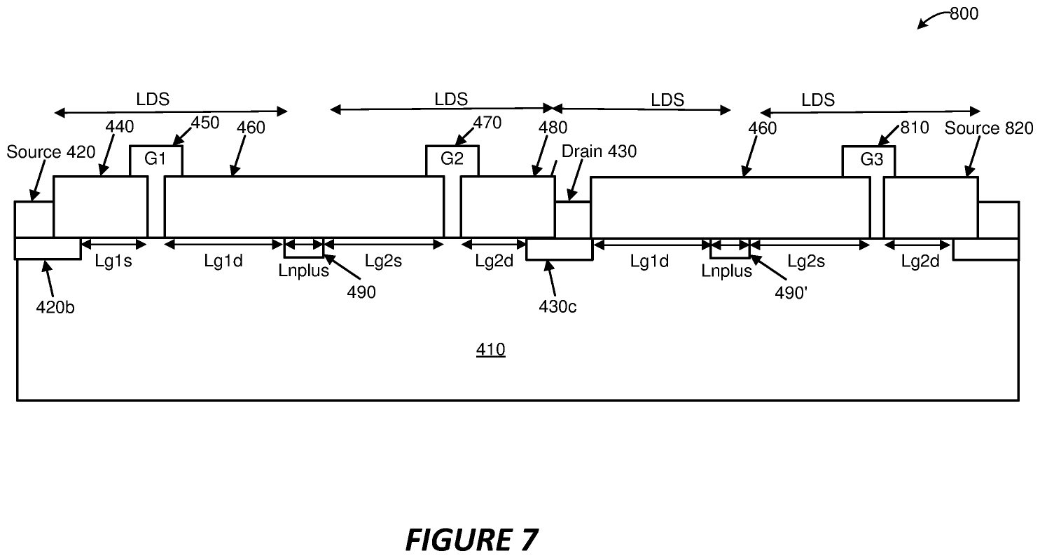

FIG. 7 is a plan view illustrating another example embodiment of a multi-gate switch FET 800 that includes a third gate (G3) 810 on the semiconductor structure 410 adjacent to the second gate (G2) 470 and between the source contact 820 and the drain contact 430. This embodiment includes a second conducting region 490′ in the semiconductor structure 410 positioned between the second gate 470 and the third gate 810.

As discussed, in some embodiments as shown in FIGS. 6 and 7, the first conducting region(s) 490 and/or 490′ includes an N-plus material.

In some embodiments, the first conducting region 490 and/or the second conducting region 490′ includes a Group Ill nitride doped with at least one of Si and Ge.

In other embodiments, the first conducting region 490 and/or the second conducting region 490′ includes a Group III nitride implanted with at least one of Si and Ge.

In yet other embodiments, the first conducting region 490 and/or the second conducting region 490′ includes a regrowth N-plus layer of GaN.

In still other embodiments, the first conducting region and/or the second conducting region 490′ includes an N-plus material and an ohmic metal on the N-plus material.

The first conducting region 490 and/or the second conducting region 490′ of the embodiments of FIGS. 6 and 7 can be positioned between a first portion of the semiconductor structure 410 and a second portion of the semiconductor structure 410.

The embodiment of FIG. 6 can correspond to the cross section shown in FIG. 5.

Thus, in some embodiments of FIG. 6, the multi-gate switch FET the conducting region 490 is positioned between a first portion of the semiconductor structure 410 and a second portion of the semiconductor structure 410. A first portion of a dielectric material 440 is on the semiconductor structure 410. The first portion of the dielectric material 440 has a first length Lg1s that extends from a first edge of the source contact 420 to a first edge of the first gate 450.

A second portion of the dielectric material 460 is on the conducting region 490 and on the first and second portions of the semiconductor substrate 410. The second portion of the dielectric material 490 includes (i) a second length Lg1d that extends from a second edge of the first gate 450 to a first edge of the conducting region 490, (ii) a third length Lnplus that extends from the first edge of the conducting region 490 to a second edge of the conducting region 490, and (iii) a fourth length Lg2s that extends from the second edge of the conducting region 490 to a second edge of the second gate 470.

Further, a third portion of the dielectric material 480 is on the semiconductor substrate 410. The third portion of the dielectric material 480 has a fifth length Lg2d that extends from a first edge of the drain contact 430 to a first edge of the second gate 470.

In some embodiments, the first length Lg1s between the source contact 420 and the first gate 450 is and the fifth length Lg2d between the drain contact 430 and the second gate have the same dimension, or about the same dimension (e.g., within manufacturing tolerances).

Further, in some embodiments, a distance between the second edge of the first gate 450 and a second edge of the second gate 470 is about equal to about the second length Lg1d plus the fourth length Lg2s plus the third length Lnplus.

In some embodiments, the first length Lg1s and the second length Lg1d have the same dimension, or about the same dimension (e.g., within manufacturing tolerances).

Further, in some embodiments, the fourth length Lg2s and the fifth length Lg2d have the same dimension, or about the same dimension (e.g., within manufacturing tolerances).

In some embodiments, the first length Lg1s, the second length Lg1d, the fourth length Lg2s, and the fifth length Lg2d have the same dimension, or about the same dimension (e.g., within manufacturing tolerances).

In some embodiments, the third length Lnplus is in a range from about 1 μm to about 4 μm.

The conducting region 490 may have a sheet resistance in a range from about 30 ohms per square to about 200 ohms per square

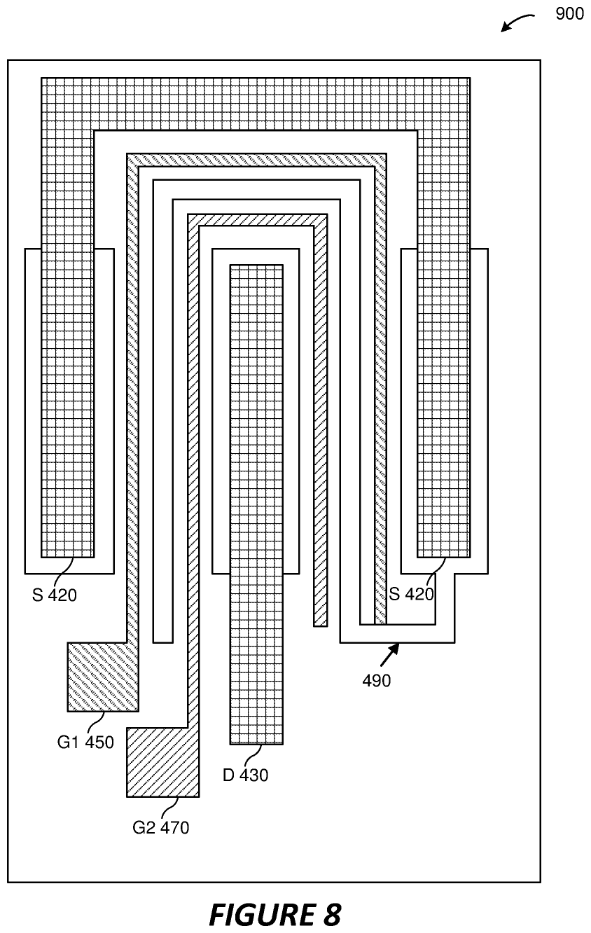

FIG. 8 is a plan view of another embodiment of a multi-gate switch FET 900. This embodiment includes a multi-finger serpentine pattern.

As shown in FIG. 8, this embodiment includes source contact 420 and drain contact 430. As shown, a first finger from first gate 450 and a second finger from second gate 470 have a serpentine pattern between the source contact 420 and the drain contract 430. The conducting region 490 is between the first gate finger and the second gate finger in the serpentine pattern.

In the example embodiment of FIG. 8, the conducting region 490 is connected to the second source contact 420. In other embodiments, however, the conducting region 490 can be connected to the drain contact and/or the first source contact 420, or to a ground.

While discussion of some embodiments herein have been discussed with operation of the switch FET with drain and source contacts referenced to ground potential, the disclosure is not so limited and embodiments include where the source and drain contacts are referenced to a non-zero bias potential.

Further, while some embodiments of multi-gate switch FETs discussed herein include two or three gates/gate fingers, the disclosure is not so limited an includes any number of gates/gate fingers greater than one.

Embodiments of the present disclosure may be advantageously employed in any planar GaN-based transistor (e.g., HEMT, MOSFET, etc.) that uses a gate electrode with a source and a drain and is designed to operate as a RF switch, microwave transmit/receive circuits, microwave front end modules (FEM), high power switch MIMICs, etc.

Embodiments of the present disclosure present significant advantages over the prior art. Advantages may include that embodiments herein may allow voltage handling to increase as in two devices in series, while having a reduced footprint compared to separate FET cells in series.

Further advantages may include that embodiments herein may allow a reduced control voltage compared to a single unstacked high voltage FET; and/or embodiments herein may avoid additional capacitance associated with an internal source/drain pad.

Yet another advantage of embodiments herein may be allowing grounding of an internal node to minimize “inner” gate-source capacitance values (e.g., Q1_Cgs and Q2_Cgd) by allowing the gate to fully reverse bias on each side of the channel. In other words, the gate maintains the symmetry of a depletion region under the device without including an additional source/drain pad which may cause an increase in the capacitance . . . .

Although embodiments of the inventive concepts have been described in considerable detail with reference to certain configurations thereof, other versions are possible. The multi-gate switch FET can also have many different configurations. Accordingly, the spirit and scope of the invention should not be limited to the specific embodiments described above.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure.

What is claimed is:

1. A multi-gate switch field effect transistor, FET, comprising:
a semiconductor structure;
a source contact on the semiconductor structure;
a drain contact on the semiconductor structure;
a first gate on the semiconductor structure between the source contact and the drain contact;
a second gate on the semiconductor structure adjacent to the first gate and between the source contact and the drain contact; and
a conducting region in the semiconductor structure between the first gate and the second gate.

2. The multi-gate switch FET of claim 1, wherein the conducting region comprises an N-plus material.

3. The multi-gate switch FET of claim 1, wherein the conducting region comprises a Group Ill nitride doped with at least one of silicon (Si) and germanium (Ge).

4. The multi-gate switch FET of claim 1, wherein the conducting region comprises a Group Ill nitride implanted with at least one of silicon (Si) and germanium (Ge).

5. The multi-gate switch FET of claim 1, wherein the conducting region comprises a regrowth N-plus layer of gallium nitride (GaN).

6. The multi-gate switch FET of claim 1, wherein the conducting region comprises an N-plus material and an ohmic metal on the N-plus material.

7. The multi-gate switch FET of claim 1, wherein the conducting region is positioned between a first portion of the semiconductor structure and a second portion of the semiconductor structure.

8. The multi-gate switch FET of claim 7, further comprising:
a first portion of a dielectric material on the semiconductor structure, the first portion of the dielectric material having a first length that extends from a first edge of the source contact to a first edge of the first gate;
a second portion of the dielectric material on the conducting region and on the first and second portions of the semiconductor substrate, the second portion of the dielectric material comprising (i) a second length that extends from a second edge of the first gate to a first edge of the conducting region, (ii) a third length that extends from the first edge of the conducting region to a second edge of the conducting region, and (iii) a fourth length that extends from the second edge of the conducting region to a second edge of the second gate; and
a third portion of the dielectric material on the semiconductor substrate, the third portion of the dielectric material having a fifth length that extends from a first edge of the drain contact to a first edge of the second gate.

9. The multi-gate switch FET of claim 8, wherein the first length and the fifth length are about the same.

10. The multi-gate switch FET of claim 8, wherein a distance between a second edge of the first gate and a second edge of the second gate is about equal to about the second length plus the fourth length plus the third length.

11. The multi-gate switch FET of claim 8, wherein the first length and the second length are about the same.

12. The multi-gate switch FET of claim 8, wherein the fourth length and the fifth length are about the same.

13. The multi-gate switch FET of claim 8, wherein the first length, the second length, the fourth length, and the fifth length are about the same.

14. The multi-gate switch FET of claim 8, wherein the third length is in a range from about 1 μm to about 4 μm.

15. The multi-gate switch FET of claim 1, wherein the conducting region has a sheet resistance in a range from about 30 ohms per square to about 200 ohms per square.

16. A multi-gate switch field effect transistor, FET, comprising:
a semiconductor structure;
a source contact on the semiconductor structure;
a drain contact on the semiconductor structure;
a first gate on the semiconductor structure between the source contact and the drain contact;
a second gate on the semiconductor structure adjacent to the first gate and between the source contact and the drain contact; and
a first conducting region in the semiconductor structure comprising a first portion positioned between the first gate and the second gate and a second portion and is connected to at least one of a ground, the source contact, and the drain contact.

17. The multi-gate switch FET of claim 16, wherein the second portion of the first conducting region is connected to the ground.

18. The multi-gate switch FET of claim 16, wherein the first gate comprises a first gate finger, the second gate comprises a second gate finger, and the second portion of the first conducting region is positioned under at least one of the first gate finger and the second gate finger.

19. The multi-gate switch FET of claim 16, further comprising:
a third gate on the semiconductor structure adjacent to the second gate and between the source contact and the drain contact; and
a second conducting region in the semiconductor structure comprising at least a third portion positioned between the second gate and the third gate.

20. The multi-gate switch FET of claim 16, wherein the first conducting region comprises an N-plus material.

21. The multi-gate switch FET of claim 16, wherein the first conducting region comprises a Group Ill nitride doped with at least one of silicon (Si) and germanium (Ge).

22. The multi-gate switch FET of claim 16, wherein the first conducting region comprises a Group Ill nitride implanted with at least one of silicon (Si) and germanium (Ge).

23. The multi-gate switch FET of claim 16, wherein the first conducting region comprises a regrowth N-plus layer of gallium nitride (GaN).

24. The multi-gate switch FET of claim 16, wherein the first conducting region comprises an N-plus material and an ohmic metal on the N-plus material.

25. The multi-gate switch FET of claim 16, wherein the first conducting region is positioned between a first portion of the semiconductor structure and a second portion of the semiconductor structure.

26. The multi-gate switch FET of claim 25, further comprising:
a first portion of a dielectric material on the semiconductor structure, the first portion of the dielectric material having a first length that extends from a first edge of the source contact to a first edge of the first gate;
a second portion of the dielectric material on the conducting region and on the first and second portions of the semiconductor substrate, the second portion of the dielectric material comprising (i) a second length that extends from a second edge of the first gate to a first edge of the conducting region, (ii) a third length that extends from the first edge of the conducting region to a second edge of the conducting region, and (iii) a fourth length that extends from the second edge of the conducting region to a second edge of the second gate; and
a third portion of the dielectric material on the semiconductor substrate, the third portion of the dielectric material having a fifth length that extends from a first edge of the drain contact to a first edge of the second gate.

27. The multi-gate switch FET of claim 26, wherein the first length and the fifth length are about the same.

28. The multi-gate switch FET of claim 26, wherein a distance between a second edge of the first gate and a second edge of the second gate is about equal to about the second length plus the fourth length plus the third length.

29. The multi-gate switch FET of claim 26, wherein the first length and the second length are about the same.

30. The multi-gate switch FET of claim 26, wherein the fourth length and the fifth length are about the same.

31. The multi-gate switch FET of claim 26, wherein the first length, the second length, the fourth length, and the fifth length are about the same.

32. The multi-gate switch FET of claim 26, wherein the third length is in a range from about 1 μm to about 4 μm.

33. The multi-gate switch FET of claim 16, wherein the conducting region has a sheet resistance in a range from about 30 ohms per square to about 200 ohms per square.
